(19) United States
(12) Patent Application Publication
(10) Pub. No.: US 2004/0097053 A1
(43) Pub. Date: May 20, 2004

(54) Semiconductor wafer protective member and semiconductor wafer grinding method

(76) Inventors: Koichi Yajima, Tokyo (JP); Yusuke Kimura, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/468,714

(22) PCT Filed: Jan. 9, 2003
(86) PCT No.: PCT/JP03/00126

(30) Foreign Application Priority Data
Jan. 11, 2002 (JP) 2002-004669

(51) Int. Cl. H01L 21/46; H01L 21/30; H01L 21/78; H01L 21/301

(52) U.S. Cl. 438/459; 438/465

(57) ABSTRACT

A grinder composed of at least a chuck table (17) having a suction region (1) and a frame (2) and grinding means (30) for grinding a semiconductor wafer (W) held on the chuck table (17) is used. When a semiconductor wafer (W) having an outside diameter Dl smaller than that of the suction region (1) is ground, a semiconductor wafer (W) protective member (3) having an outside diameter D3 larger than the outside diameter Dl of the semiconductor wafer and larger than the diameter D2 of the suction region (1) is stuck on the side not to be ground of the semiconductor wafer (W). The whole surface of the semiconductor wafer (W) is held on the suction region (1), with the semiconductor wafer protective member (3) down. The exposed surface of the held semiconductor wafer (W) is ground by the grinding means (30). Thus the edge of the semiconductor wafer (W) is prevented from breaking, chipping and cracking.

### TECHNICAL FIELD

The present invention relates to a protective member to be applied to a semiconductor wafer for protecting one of its major surfaces in grinding the other major surface, and a grinding method using the protective member.

### BACKGROUND ART

Referring to FIG. 4, a semiconductor wafer W1 has squares delimited by the crossing streets S, each square has IC or LSI circuit patterns formed therein. After grinding the semiconductor wafer on the rear surface until a predetermined thickness has been reached, the semiconductor wafer is diced into separate chips C individually with each circuit.

Referring to FIG. 5, crosswise grooves 60 as deep as the thickness of the semiconductor chip to be completed are formed on the streets S of a semiconductor wafer W2 in advance, and the so grooved wafer is ground on the rear surface to divide into separate semiconductor chips C. This is called “Prior Dicing” process.

In either case, an adhesive protection tape T having the same size as the semiconductor wafer W1 or W2, is applied to the front surface of the semiconductor wafer, and the semiconductor wafer is laid on the chuck table 70 with the protection tape T sandwiched therebetween and sucked thereon. While rotating, the grindstone 73 is lowered until it comes to contact with the rear surface of the semiconductor wafer W1 or W2. Thus, the wafer is ground on the rear surface to reach a desired thickness.

Cellular phones, personal computers and other electronic devices have been reduced in size these years. To meet such tendency of downsizing it is required that semiconductor wafers are 100 or less μm thick or even 50 μm thick.

Referring to FIG. 6, the chuck table 70 comprises a suction region 71 and a frame 72 encircling the suction region 71. The suction region 71 is somewhat smaller in diameter than the overlying semiconductor wafer W1 or W2 to prevent the drawing of extra amount of air to fixedly hold the semiconductor wafer W1 or W2 thereon and also prevent invading of minute debris to be caused by grinding.

The annular part of the overlying wafer W1 or W2 radially extending beyond the suction region 71 cannot be drawn and stuck to the suction region 71, and therefore, the annular margin of the semiconductor wafer cannot be fixedly held. While the semiconductor wafer is being ground on the rear surface, the annular margin of the wafer is made flutter, often causing crack, chipping or the like.

In case the semiconductor wafer is 100 or less μm thick, it is very likely to cause cracks when peeling the protection tape T off from the semiconductor wafer. This problem cannot be solved even if use is made of a polyethylene terephthalate (PET) tape, which is high in rigidity.

Similarly pre-diced semiconductor wafers allow their annular margins to flutter and crack while being ground.

What is aimed at by the present invention is to prevent semiconductor wafers from cracking while being ground.

### DISCLOSURE OF INVENTION

A semiconductor wafer protective member for use in sucking a semiconductor wafer onto the suction region of the chuck table, which has a frame encircling the suction region, the semiconductor wafer being smaller in diameter than the suction region, is improved according to the present invention in that the semiconductor wafer protective member is larger in diameter than the semiconductor wafer, and than the suction region.

The suction region may be 0.5 millimeters larger in diameter than the semiconductor wafer, and the semiconductor wafer protective member may be 0.5 millimeters larger in diameter than the suction region. The semiconductor wafer protective member may be a sheet of synthetic resin having an adhesive layer on one surface. The adhesive layer may be sensitive to ultraviolet rays for losing its adhesive power, or may be of ultra violet setting type. The synthetic resin may be polyethylene terephthalate. A method of grinding semiconductor wafers with a grinding apparatus including at least chuck tables each having a suction region for sucking and fixedly holding a semiconductor wafer, and a frame encircling the suction region, is improved according to the present invention in that the suction region is larger in diameter than the semiconductor wafer, and that the method comprises the steps of: applying to the front surface of the semiconductor wafer a semiconductor protective member, which is larger than the suction region; putting the semiconductor wafer on the suction region with the semiconductor protective member sandwiched therebetween; and grinding the exposed rear surface of the semiconductor wafer.

In this method of grinding semiconductor wafers, the suction region may be 0.5 millimeters larger in diameter than the semiconductor wafer, and the semiconductor wafer protective member may be 0.5 millimeters larger in diameter than the suction region. The semiconductor wafer protective member may be a sheet of synthetic resin having an adhesive layer on one surface. The adhesive layer may be sensitive to ultraviolet rays for losing its adhesive power, or may be of ultra violet setting type. The synthetic resin may be polyethylene terephthalate.

According to the semiconductor wafer protective member and the method of grinding semiconductor wafers according to the present invention as described above, the semiconductor wafer is smaller than the suction region of the chuck table, thus the whole area of the semiconductor wafer can be stuck to the suction region, while the semiconductor wafer protective member is larger in diameter than the suction region, thus preventing suction of extra amount of air while allowing its circumference to be stuck to the suction region. Thus, the semiconductor wafer is prevented from fluttering on its circumference while being ground, and the semiconductor wafer cannot crack on its circumference.

### BRIEF DESCRIPTION OF DRAWINGS

FIG. 1 is a perspective view of a grinding machine for use of carrying out the present invention;

FIG. 2 is a perspective view illustrating a semiconductor wafer having a protective member applied to its front surface, and the chuck table of the grinding machine;

FIG. 3 illustrates how the semiconductor wafer is ground;

FIG. 4 is a perspective view of a semiconductor wafer;

FIG. 5 is a perspective view of another semiconductor wafer having crosswise grooves made thereon; and

FIG. 6 illustrates the conventional grinding manner in which a semiconductor wafer is ground.

### BEST MODE FOR CARRYING OUT THE INVENTION

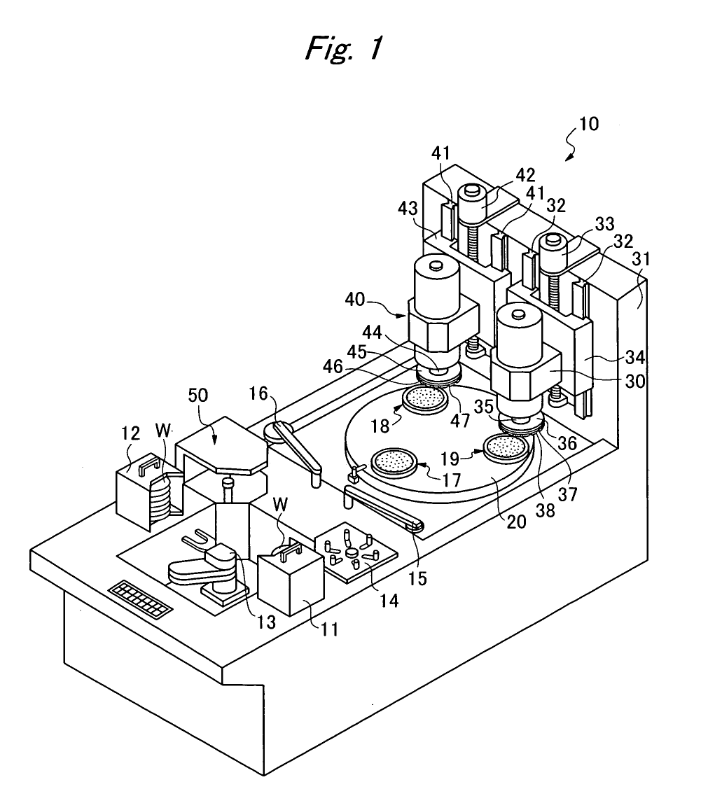

As an example of the embodiments of the present invention, it is described how the rear surface of the semiconductor wafer is ground with us of a grinding machine 10 as shown in FIG. 1.

The grinding machine 10 comprises first and second cassettes 11 and 12 for storing semiconductor wafers W, transporting means 13 for taking wafers out of the cassette 11 and putting wafers in the cassette 12, orienting means 14 for orienting wafers W, first and second wafer transporting means 15 and 16, three chuck tables 17, 18 and 19 for sucking and holding wafers, a turn table 20 having the chuck tables rotatably fixed thereon, first and second grinding tools 30 and 40 and rinsing means 50 for washing and cleaning wafers after being ground.

In operation semiconductor wafers W are taken out one after another from the first cassette 11 by the transporting means 13, and the wafer W thus taken out is transferred to the orienting means 14 where it is oriented. Then, it is transferred by the first transporting means 15 to a selected chuck table 17 to be laid thereon.

The chuck tables 17, 18 and 19 can rotate about their pivots, and they can revolve about the pivot of the turntable 20 when the turntable 20 rotates about its pivot. In the figured example, the chuck tables 17 with sucking and holding a semiconductor wafer W can be brought right below the first grinding means 30 the turn table 17 by rotating 120 degrees counter clockwise.

The first grinding means 30 fixed to a movable mount 34. It rides on a pair of parallel guide rails 32, which are laid on the upright wall 31 of the base of the grinding machine 10. A mount drive 33 is attached to the top of the upright wall 31 to drive the movable mount 34 vertically on the parallel guide rails 32. The first grinding means 30 has a spindle 35 rotatably supported on its center axis, and the spindle 35 has a grinding wheel 37 via a mount piece 36, and a circular coarse-grinding stone 38 attached to the lower end of the grinding wheel 37.

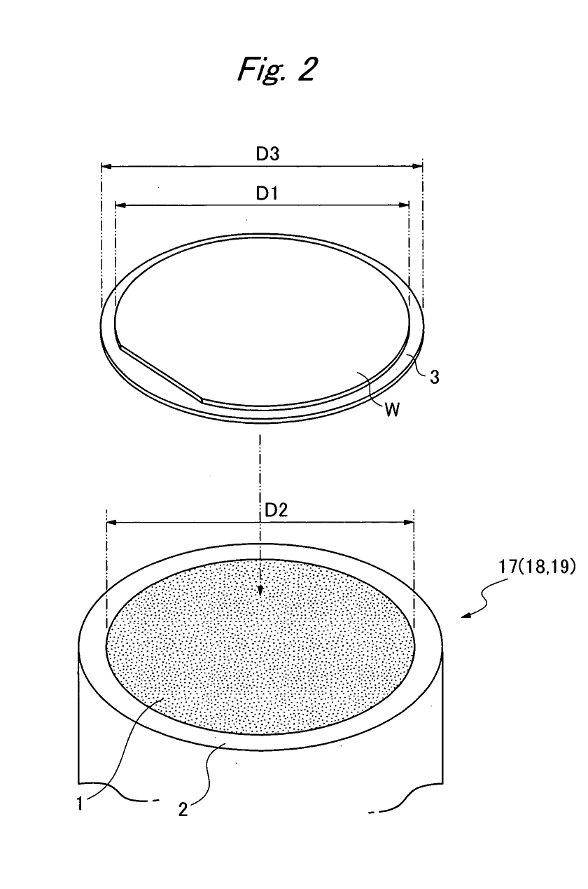

As seen from FIG. 2, the chuck table 17, 18 or 19 has an air-permeable suction region 1 of porous ceramics material, and a frame 2 encircling the suction region 1. The suction region 1 is connected on its lower side to the suction source (not shown), which draws air through the suction region 1, thereby pulling and fixedly sticking a semiconductor wafer W.

As shown in the drawing, the semiconductor wafer W has a protective member 3 applied to its front surface to protect the circuit patterns formed thereon. The protective member 3 may be an adhesive tape or a piece of synthetic resin having an adhesive layer on one side.

The adhesive layer may be of UV setting type, which is sensitive to ultraviolet rays for reducing its adhesive power. Later exposure of the adhesive layer to ultraviolet rays facilitates the peeling-off of the protective member from the semiconductor wafer W.

The protective member 3 may be advantageously formed of a rigid material such as polyethylene terephthalate (PET); semiconductor wafers lined with such rigid protective members can be easily transported without fear of cracking or chipping.

The diameter D1 of the semiconductor wafer W is smaller than the diameter D2 of the suction region 1 of the chuck table 17. For example, the diameter D2 is 0.5 or more millimeters larger than the diameter D1.

On the other hand, the diameter D3 of the protective member 3 is larger than the diameter D1 of the semiconductor wafer W, and is larger than the diameter D2 of the suction region 1 of the chuck table 17, 18 or 19. For example, the diameter D3 is 0.5 or more millimeters larger than the diameter D2. Thus, the dimensional relation is given by: D1<D2<D3.

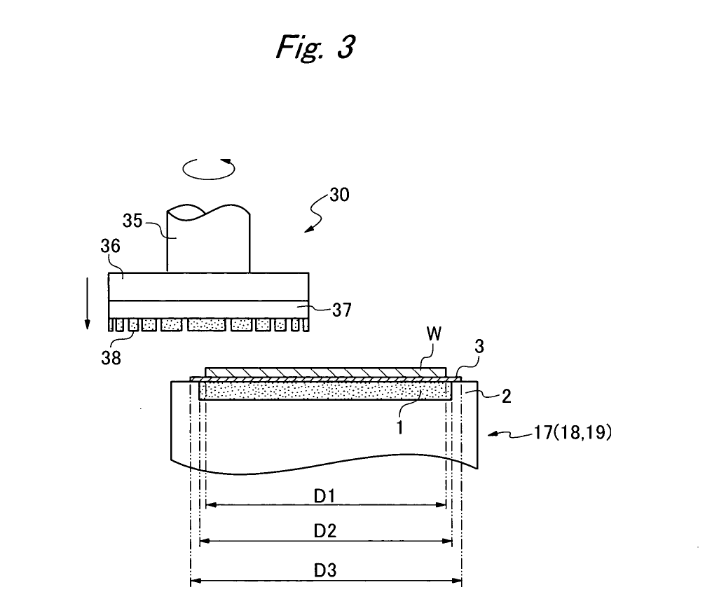

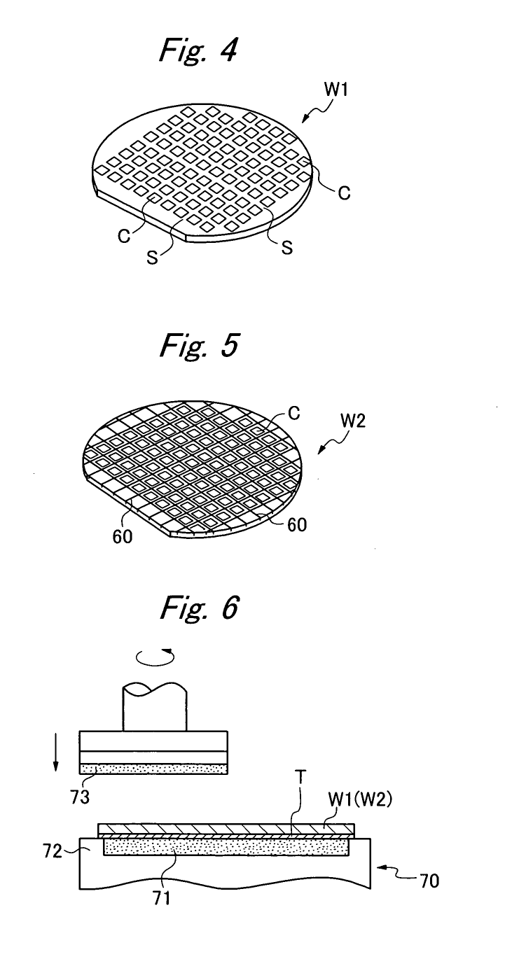

The semiconductor wafer W having the protective member 3 applied to its front surface, is put on the suction region 1 of the chuck table 17 with the protective member 3 sandwiched therebetween, as shown in FIG. 3. The protective member 3 extends beyond the circumference of the underlying suction region 1. The diameter D1 of the semiconductor wafer W is smaller than the diameter D2 of the suction region 1, and therefore, the whole area of the semiconductor wafer W is pulled and fixedly stuck to the suction region 1 via the intervening protective member 3.

As seen from FIG. 3, the first grinding means 30 is lowered while its spindle 35 is rotating, and the semiconductor wafer W is put just below the first grinding means 30, and it is ground to the desired thickness when the coarse grinding stone 38 is put in contact with its rear surface (or exposed surface).

As the protective member 3 completely covers the whole suction region 1 of the chuck table 17, preventing suction of the surrounding air to fixedly hold the semiconductor wafer W with strong sucking force, and whole area of the semiconductor wafer W is sucked and held with the suction region 1. Thus, the semiconductor wafer W cannot be adversely affected even though the protective member flutters on its circumference, and the semiconductor wafer W is guaranteed to be free of cracking or chipping. Thus, the ground semiconductor wafers of high quality can be provided.

Referring to FIG. 1 again, the turntable 28 rotates another predetermined angle counter clockwise to put the coarse-ground semiconductor wafer right below the second grinding means 40.

The second grinding means 40 is fixed to an associated movable mount 43. It rides on a pair of parallel guide rails 41, which are laid on the upright wall 31. A mount drive 42 is attached to the top of the upright wall 31 to drive the movable mount 43 vertically on the parallel guide rails 41. The second grinding means 40 has a spindle 44 rotatably supported on its center axis, and the spindle 44 has a grinding wheel 46 via a mount piece 45, and a circular fine-grinding stone 47 attached to the lower end of the grinding wheel 46. The second grinding means 40 is different from the first grinding means 30 only in the kind of the grinding stone.

The second grinding means 40 is lowered while its spindle 44 is rotating, and the coarse-ground wafer W positioned just below the second grinding means 40 is fine-ground when the fine grinding stone 47 is put in contact with the rear surface (or exposed surface) of the coarse-ground semiconductor wafer W. Thus, the semiconductor wafer is fine ground.

As is the case with the coarse-grinding, the protective member 3 completely covers the whole suction region 1 also in the fine grinding, preventing suction of the surrounding air to fixedly hold the semiconductor wafer W with strong sucking force, and whole area of the semiconductor wafer W is sucked and held with the suction region 1. Thus, the semiconductor wafer W cannot be adversely affected even though the protective member flutters on its circumference, and the semiconductor wafer W is guaranteed to be free of cracking or chipping.

The semiconductor wafers thus fine-ground are transferred to the rinsing means 50 by the second transport means 16 to wash away minute debris from the semiconductor wafers, and then the wafers thus cleaned are transferred and put in the second cassette 12.

The fine-grounded semiconductor wafers are free of cracks and chips, and their quality is assured.

The grinding method according to the present invention is described as being applied to the coarse-and-fine grinding steps. Needless to say, it can be equally applied to the grinding method comprising one grinding step, or three or more grinding steps.

The semiconductor wafer to be ground is described as having a protective member applied to its front surface, thereby protecting the circuit patterns formed thereon. When a semiconductor wafer having no circuit patterns formed thereon, the semiconductor wafer may have its protective member applied to its rear surface, allowing the grinding means to grind its front surface.

Further, the grinding method can be equally applied to pre-diced semiconductor wafers, and then, the squares arranged close to its circumference can be guaranteed to be free of cracking and chipping.

Industrial Applicability

As may be understood from the above, according to the semiconductor wafer protective member and the method of grinding semiconductor wafers using the same according to the present invention, the semiconductor wafer is smaller than the suction region of the chuck table, so that the whole area may be sucked and stuck on the chuck table. On the other hand, the protective member applied to the semiconductor wafer is larger than the suction region of the chuck table so that the suction region may be prevented from drawing air from the surrounding atmosphere, thus assuring that the whole area of the semiconductor wafer including its circumference is fixedly held on the chuck table. The so fixedly held semiconductor wafer when ground, cannot be adversely affected even though the protection member flutters on its circumference, and the semiconductor wafer is assured to be free from cracking or chipping. Thus, crack-free, ground semiconductor wafers are provided. Thus, the quality of semiconductor wafers is improved.

1. A semiconductor wafer protective member for use in sucking a semiconductor wafer onto the suction region of the chuck table, which has a frame encircling the suction region, the semiconductor wafer being smaller in diameter than the suction region, characterized in that the semiconductor wafer protective member is larger in diameter than the semiconductor wafer, and than the suction region.

2. A semiconductor wafer protective member according to claim 1, wherein the suction region is 0.5 millimeters larger in diameter than the semiconductor wafer, and the semiconductor wafer protective member is 0.5 millimeters larger in diameter than the suction region.

3. A semiconductor wafer protective member according to claim 1, wherein the semiconductor wafer protective member is a sheet of synthetic resin having an adhesive layer on its front surface.

4. A semiconductor wafer protective member according to claim 3, wherein the adhesive layer is sensitive to ultraviolet rays for losing its adhesive power, or of ultra violet setting type.

5. A semiconductor wafer protective member according to claim 3 or 4, wherein the synthetic resin is polyethylene terephthalate.

6. A method of grinding semiconductor wafers with a grinding apparatus including at least chuck tables each comprising a suction region for sucking and fixedly holding a semiconductor wafer, and a frame encircling the suction region characterized in that the suction region is larger in diameter than the semiconductor wafer, and that the method comprises the steps of:
applying to the front surface of the semiconductor wafer a semiconductor protective member, which is larger than the suction region;
putting the semiconductor wafer on the suction region with the semiconductor protective member sandwiched therebetween; and
grinding the exposed rear surface of the semiconductor wafer.

7. A method of grinding semiconductor wafers with a grinding apparatus according to claim 6, wherein the suction region is 0.5 millimeters larger in diameter than the semiconductor wafer, and the semiconductor wafer protective member is 0.5 millimeters larger in diameter than the suction region.

8. A method of grinding semiconductor wafers with a grinding apparatus according to claim 6, wherein the semiconductor wafer protective member is a sheet of synthetic resin having an adhesive layer on its front surface.

9. A method of grinding semiconductor wafers with a grinding apparatus according to claim 8, wherein the adhesive layer is sensitive to ultraviolet rays for losing its adhesive power, or is of ultra violet setting type.

10. A method of grinding semiconductor wafers with a grinding apparatus according to claim 9, wherein the synthetic resin is polyethylene terephthalate.
